(19) United States
(12) Patent Application Publication
(10) Pub. No.: US 2024/0207996 A1
(43) Pub. Date: Jun. 27, 2024

(54) SUBSTRATE POLISHING APPARATUS

(71) Applicant: EBARA CORPORATION, Tokyo (JP)

(72) Inventors: Yasumasa HIROO, Tokyo (JP); Masaki KINOSHITA, Tokyo (JP)

(21) Appl. No.: 18/396,256

(22) Filed: Dec. 26, 2023

(30) Foreign Application Priority Data
Dec. 27, 2022 (JP) 2022-209808

(51) Int. Cl. B24B 37/013

(52) U.S. Cl. CPC B24B 37/013

(57) ABSTRACT

To remove or reduce the influence on the measurement accuracy due to a difference of the relative velocity between a substrate and a polishing table in an optical surface monitoring system. A substrate polishing apparatus includes a polishing table, a motor, a substrate holding head, a light source, an optical head, an optical detector, a shutter, and a control device. The motor is for rotating the polishing table. The substrate holding head is configured to hold a substrate. The optical head is disposed inside the polishing table. The optical head includes a light projection port and a light reception port. The light projection port is disposed to project light from the light source toward the substrate held by the substrate holding head. The light reception port is disposed to receive light reflected from the substrate held by the substrate holding head. The optical detector is for detecting the light received at the light reception port. The shutter is for controlling an exposure time during which the light is captured in the optical detector. The control device is for controlling the operation of the shutter so as to change the exposure time based on the polishing condition of the substrate.

### CROSS REFERENCE TO RELATED APPLICATION

This application claims priority to Japanese Patent Application No. 2022-209808, filed on Dec. 27, 2022, the entire contents of which are hereby incorporated by reference.

### TECHNICAL FIELD

This application relates to a substrate polishing apparatus.

### BACKGROUND ART

A chemical mechanical polishing (CMP) apparatus is used to planarize a surface of a substrate in the production of semiconductor devices. Substrates used in the production of semiconductor devices often have a circular plate shape. Usually, the CMP apparatus includes a polishing table that supports a polishing pad, a substrate holding head that presses a substrate to the polishing pad, and a slurry supply nozzle that supplies slurry onto the polishing pad. While the polishing table is rotated, the slurry is supplied to the polishing pad on the polishing table, and the substrate holding head presses the substrate to the polishing pad. In the CMP apparatus, the substrate is polished by moving the substrate relatively to the polishing pad while pressing the substrate to the polishing pad in the presence of the slurry. The surface of the substrate is planarized by combination of chemical action of the slurry and mechanical action of abrasive grains included in the slurry.

Polishing of the substrate is finished when the thickness of a film (such as an insulating film, a metallic film, and a silicon layer) constituting the surface reaches a predetermined target value. The CMP apparatus includes an optical surface monitoring system to measure the thickness of a non-metallic film such as the insulating film and the silicon layer in some cases. The optical surface monitoring system is configured to detect the surface condition of the substrate (for example, measure the film thickness of the substrate, or detect removal of the film constituting the surface of the substrate) by guiding light emitted from a light source to the surface of the substrate, measuring the intensity of reflected light from the substrate with a spectroscope, and analyzing a spectrum of the reflected light.

### CITATION LIST

### Patent Literature

PTL 1: Japanese Unexamined Patent Application Publication No. 2020-142303
PTL 2: Japanese Unexamined Patent Application Publication No. 2017-220683

### SUMMARY OF INVENTION

### Technical Problem

A xenon flash lamp is used as a light source in some cases. The xenon flash lamp is a pulse lighting light source having a lighting time on the order of several microseconds. The xenon flash lamp is capable of emitting multi-wavelength light from about 200 nm to 1100 nm.

While the xenon flash lamp has an advantage of being able to provide a large amount of light in a short lighting time, the amount of light varies for each pulse. When performing some measurements by using the xenon flash lamp, in order to suppress the influence of the variation in the amount of light for each pulse, the identical measurement position is irradiated with pulse light multiple times to perform multiple measurements, and measured values are added up, or an average value is calculated, in some cases. However, when the xenon flash lamp is used as a light source for the optical surface monitoring system of the CMP apparatus, since both of the substrate and the polishing table where the light source is disposed are rotating, it is difficult to irradiate the identical measurement position on the substrate with the pulse light multiple times. Even when it is possible to irradiate the identical measurement position on the substrate with the pulse light multiple times, while the identical measurement position is irradiated with the pulse light multiple times, polishing of the substrate progresses, resulting in a change in the condition of the surface of the substrate.

Therefore, when processing to suppress a light emission variation is performed, as a light source for the optical surface monitoring system of the CMP apparatus, one measure is to employ a continuous light-emitting light source (or a CW light source, namely, a Continuous Wave light source, also referred to as a continuous wave light source) that is always on and has a stable amount of light. When the CW light source is used, in order to measure the surface condition of a predetermined position on the substrate, it is necessary to cut out a part of CW light. While a shutter is used to cut out a part of the CW light, the time length in which the part of the CW light can be cut out with the shutter generally becomes longer than the lighting time of the xenon flash lamp.

In the CMP apparatus, during polishing of the substrate, since the polishing table on which the optical surface monitoring system is disposed is constantly rotating, a region on the substrate that is exposed for a certain period of time varies depending on the relative velocity of the polishing table and a measurement position on the substrate. Thus, since the area of a measurement region on the substrate varies depending on the relative velocity of the measurement position on the substrate, the measurement accuracy of the substrate surface changes.

When the CW light source and the shutter are used in the optical surface monitoring system, since an exposure time becomes longer than a case of using a pulsed light source such as the xenon flash lamp, it is susceptible to a difference of the relative velocity between the substrate and the polishing table as described above.

Therefore, it is an object of this application to remove or reduce the influence on the measurement accuracy due to the difference of the relative velocity between the substrate and the polishing table as described above in the optical surface monitoring system.

### Solution to Problem

According to one embodiment, a substrate polishing apparatus is provided. The substrate polishing apparatus includes a polishing table, a motor, a substrate holding head, a light source, an optical head, an optical detector, a shutter, and a control device. The motor is for rotating the polishing table. The substrate holding head is configured to hold a substrate. The optical head is disposed inside the polishing table. The optical head includes a light projection port and a light reception port. The light projection port is disposed to project light from the light source toward the substrate held by the substrate holding head. The light reception port is disposed to receive light reflected from the substrate held by the substrate holding head. The optical detector is for detecting the light received at the light reception port. The shutter is for controlling an exposure time during which the light is captured in the optical detector. The control device is for controlling the operation of the shutter so as to change the exposure time based on the polishing condition of the substrate.

### BRIEF DESCRIPTION OF DRAWINGS

FIG. 1 is a schematic diagram illustrating one embodiment of a substrate polishing apparatus;

FIG. 2 is a cross-sectional view illustrating one embodiment of a detailed configuration of the substrate polishing apparatus illustrated in FIG. 1;

FIG. 3 is a diagram schematically illustrating a positional relationship between a polishing table and a substrate held by a substrate holding head in a state where the polishing table and the substrate holding head are halted, and is a diagram illustrating a measurement region (an irradiated region) on the substrate in a certain exposure time;

FIG. 4 is a diagram schematically illustrating a positional relationship between the polishing table and the substrate held by the substrate holding head in a state where the polishing table is relatively rotating at a low velocity and the substrate holding head is halted, and is a diagram illustrating the measurement region (the irradiated region) on the substrate W in a certain exposure time;

FIG. 5 is a diagram schematically illustrating a positional relationship between the polishing table and the substrate held by the substrate holding head in a state where the polishing table is relatively rotating at a high velocity and the substrate holding head is halted, and is a diagram illustrating the measurement region (the irradiated region) on the substrate in a certain exposure time;

FIG. 6 is a diagram schematically illustrating a positional relationship between the polishing table and the substrate held by the substrate holding head in a state where a plurality of optical sensor heads are disposed in a radial direction of the polishing table, the polishing table is rotating, and the substrate holding head is halted, and is a diagram illustrating the measurement region (the irradiated region) on the substrate W in a certain exposure time;

FIG. 7 is a diagram schematically illustrating a positional relationship between the polishing table and the substrate held by the substrate holding head in a state where the polishing table and the substrate holding head are rotating, and is a diagram illustrating the measurement region (the irradiated region) on the substrate in a certain exposure time; and

FIG. 8 is a diagram schematically illustrating a positional relationship between the polishing table and the substrate held by the substrate holding head in a state where the polishing table is rotating and the substrate holding head is rotating while swinging, and is a diagram illustrating the measurement region (the irradiated region) on the substrate in a certain exposure time.

### DESCRIPTION OF EMBODIMENTS

The following describes embodiments of a substrate polishing apparatus according to the present invention with reference to attached drawings. In the attached drawings, identical or similar reference numerals are given to identical or similar components, and in an explanation of each embodiment, overlapping explanations regarding the identical or similar components are omitted in some cases. Features indicated in each embodiment are also applicable to other embodiments as long as they do not conflict with one another.

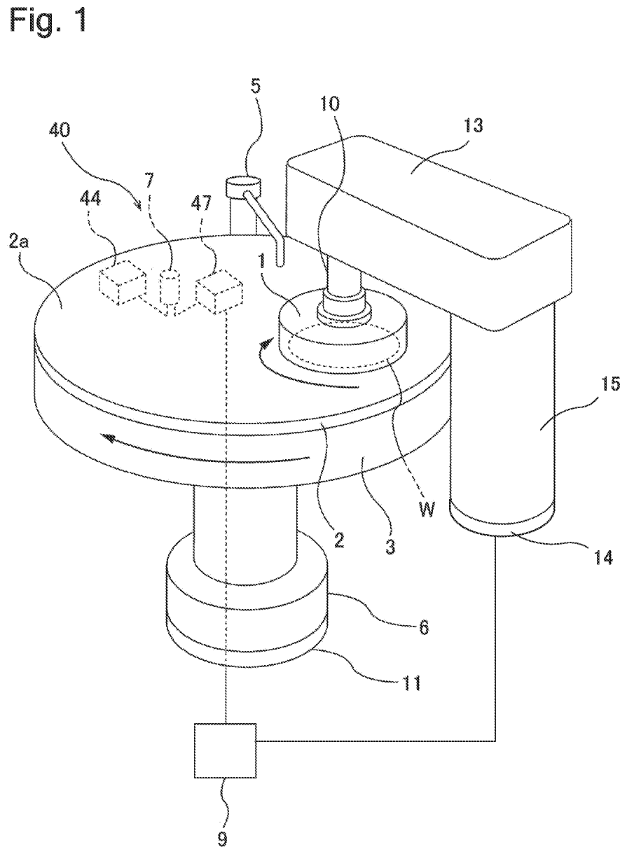

FIG. 1 is a schematic diagram illustrating one embodiment of the substrate polishing apparatus. As illustrated in FIG. 1, the substrate polishing apparatus includes a polishing table 3 that supports a polishing pad 2, a substrate holding head 1 for holding a substrate W, a table motor 6 that rotates the polishing table 3, and a slurry supply nozzle 5 for supplying slurry onto the polishing pad 2.

The substrate holding head 1 is coupled to a head shaft 10, and the substrate holding head 1 can rotate together with the head shaft 10 in a direction indicated by an arrow. As illustrated in FIG. 1, the head shaft 10 is mounted to an arm 13. The arm 13 is configured to be turnable around a support pillar 15. The substrate polishing apparatus includes a rotary encoder 14 that detects a rotation angle of the arm 13. The rotary encoder 14 is coupled to a motor that turns the arm 13 and that is not illustrated.

The polishing table 3 is coupled to the table motor 6, and the table motor 6 is configured to rotate the polishing table 3 and the polishing pad 2 in a direction indicated by an arrow. The substrate polishing apparatus includes a rotary encoder 11 that detects a rotation angle of the polishing table 3. The rotary encoder 11 is coupled to the table motor 6.

The substrate W is polished as follows. The slurry is supplied to a polishing surface 2a of the polishing pad 2 on the polishing table 3 from the slurry supply nozzle 5 while the polishing table 3 and the substrate holding head 1 are rotated in the direction indicated by the arrow in FIG. 1. The substrate W is pressed to the polishing surface 2a of the polishing pad 2 in a state where the slurry is present on the polishing pad 2 while the substrate W is being rotated by the substrate holding head 1. Furthermore, during polishing of the substrate, the substrate holding head 1 may be swung on the polishing pad 2 by turning the arm 13. The surface of the substrate W is polished by chemical action of the slurry and mechanical action by abrasive grains included in the slurry.

The substrate polishing apparatus includes an optical surface monitoring system 40 that detects the surface condition of the substrate W. The optical surface monitoring system 40 includes an optical sensor head 7, a CW light source 44, a spectroscope 47, a trigger sensor 25, and a control device 9. The optical sensor head 7, the CW light source 44, and the spectroscope 47 are mounted to the polishing table 3 and integrally rotate together with the polishing table 3 and the polishing pad 2. The position of the optical sensor head 7 is a position that traverses the surface of the substrate W on the polishing pad 2 each time the polishing table 3 and the polishing pad 2 rotate once. In another embodiment, instead of the CW light source 44, a pulsed light source such as a xenon flash lamp may be used.

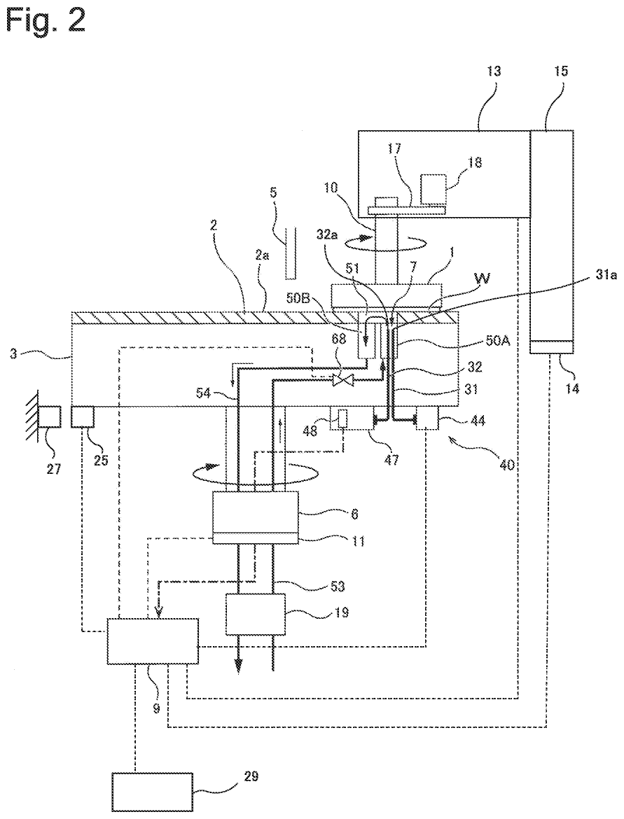

FIG. 2 is a cross-sectional view illustrating one embodiment of a detailed configuration of the substrate polishing apparatus illustrated in FIG. 1. The head shaft 10 is coupled to a substrate holding head motor 18 via a coupling device 17 such as a belt and is rotated. By the rotation of the head shaft 10, the substrate holding head 1 rotates in a direction indicated by an arrow.

The spectroscope 47 includes an optical detector 48. In one embodiment, the optical detector 48 is an image sensor such as a CCD or a CMOS. The optical sensor head 7 is optically coupled to the CW light source 44 and the optical detector 48. The CW light source 44 and the optical detector 48 are electrically connected to the control device 9.

The optical surface monitoring system 40 further includes a light projection optical fiber cable 31 that guides light emitted from the CW light source 44 to the surface of the substrate W and a light reception optical fiber cable 32 that receives reflected light from the substrate W and transmits the reflected light to the spectroscope 47. A distal end of the light projection optical fiber cable 31 constitutes a light projection port 31a that projects the light toward the substrate held by the substrate holding head 1. A distal end of the light reception optical fiber cable 32 constitutes a light reception port 32a that receives the light reflected from the substrate held by the substrate holding head 1. The light projection port 31a and the light reception port 32a are located inside the polishing table 3 so as to face toward the substrate held by the substrate holding head 1.

The light projection port 31a, which is the distal end of the light projection optical fiber cable 31, and the light reception port 32a, which is the distal end of the light reception optical fiber cable 32, guide the light to the surface of the substrate W and constitute the optical sensor head 7 that receives the reflected light from the substrate W. The other end of the light projection optical fiber cable 31 is connected to the CW light source 44, and the other end of the light reception optical fiber cable 32 is connected to the spectroscope 47. The spectroscope 47 is configured to decompose the reflected light from the substrate W in accordance with wavelengths and measure intensity of the reflected light over a predetermined wavelength range.

The light emitted from the CW light source 44 is transmitted to the optical sensor head 7 through the light projection optical fiber cable 31 and emitted toward the substrate W from the light projection port 31a. The reflected light from the substrate W is received by the light reception port 32a and transmitted to the spectroscope 47 through the light reception optical fiber cable 32. The spectroscope 47 decomposes the reflected light in accordance with the wavelengths and measures the intensity of the reflected light at each wavelength. The spectroscope 47 transmits measurement data of the intensity of the reflected light to the control device 9.

The control device 9 generates a spectrum of the reflected light from the measurement data of the intensity of the reflected light. This spectrum indicates a relationship between the intensity and the wavelength of the reflected light, and the shape of the spectrum changes in accordance with the film thickness of the substrate W. The control device 9 determines the film thickness of the substrate W from the spectrum of the reflected light. A known technique is used for a method for determining the film thickness of the substrate W from the spectrum of the reflected light. For example, the Fourier transformation is performed on the spectrum of the reflected light, and the film thickness is determined from an obtained frequency spectrum.

During polishing of the substrate, each time the polishing table 3 rotates once, the optical sensor head 7 irradiates a measurement point on the substrate W with the light while traversing the surface of the substrate W on the polishing pad 2 and receives the reflected light from the substrate W. The control device 9 determines the film thickness of the substrate W from the measurement data of the intensity of the reflected light and controls the polishing operation of the substrate W based on the film thickness. For example, the control device 9 determines a polishing end point that is a time point when the film thickness of the substrate W reaches a target film thickness.

As one embodiment, the control device 9 can be constituted of a general computer including an input/output device, an arithmetic device, a storage device, and the like. The control device 9 may be disposed inside the polishing table 3 and rotate together with the polishing table 3 or may be disposed outside the polishing table 3 and unrotatable together with the polishing table 3.

In one embodiment, the substrate polishing apparatus includes an operation PC 29. The operation PC constitutes a user interface of the substrate polishing apparatus and allows a user to specify polishing conditions such as the rotation speed of the polishing table 3, and the like. The operation PC 29 can be constituted of a general computer including an input/output device, an arithmetic device, a storage device, and the like. Functions of the control device 9 and the operation PC 29 are interchangeable with one another, and any of the control device 9 and the operation PC 29 may perform control of the operation and calculation processing inside the substrate polishing apparatus.

In one embodiment, the control device 9 may detect a state where a film constituting the surface of the substrate W is removed from a change in the spectrum of the reflected light. In this case, the control device 9 determines a polishing end point that is a time point when the film constituting the surface of the substrate W is removed. The control device 9 need not determine the film thickness of the substrate W from the spectrum of the reflected light.

The polishing table 3 has a first hole 50A and a second hole 50B that have an opening on its upper surface. A through hole 51 is formed at a position corresponding to these holes 50A and 50B in the polishing pad 2. The holes 50A and 50B communicate with the through hole 51, and the through hole 51 is open at the polishing surface 2a. The first hole 50A is coupled to a liquid supply line 53, and the second hole 50B is coupled to a drain line 54. The optical sensor head 7 constituted of the distal end of the light projection optical fiber cable 31 and the distal end of the light reception optical fiber cable 32 is disposed in the first hole 50A and is located below the through hole 51.

In one embodiment, a halogen light source, a plasma light source, a deuterium light source, or the like can be used as the CW light source 44. The light projection optical fiber cable 31 is a light transmission portion that guides the light emitted by the CW light source 44 to the surface of the substrate W. The light projection port 31a and the light reception port 32a are located inside the first hole 50A and are located near a surface to be polished of the substrate W. The optical sensor head 7 constituted of the light projection port 31a and the light reception port 32a, which are respective distal ends of the light projection optical fiber cable 31 and the light reception optical fiber cable 32, is disposed so as to face the substrate W held by the substrate holding head 1. The substrate W is irradiated with the light each time the polishing table 3 rotates. In this embodiment, only one optical sensor head 7 is disposed, but a plurality of optical sensor heads 7 may be disposed.

During polishing of the substrate W, the optical sensor head 7 travels across the substrate W each time the polishing table 3 rotates once. While the optical sensor head 7 is below the substrate W, the CW light source 44 always emits the light. The light is guided to the surface (the surface to be polished) of the substrate W through the light projection optical fiber cable 31, and the reflected light from the substrate W is received by the spectroscope 47 through the light reception optical fiber cable 32 and is captured in the optical detector 48. The optical detector 48 measures the intensity of the reflected light at each wavelength over the predetermined wavelength range and transmits the obtained measurement data to the control device 9. The measurement data is a film thickness signal varying in accordance with the film thickness of the substrate W. The control device 9 generates the spectrum of the reflected light that represents the intensity the light for each wavelength from the measurement data and further determines the film thickness of the substrate W from the spectrum of the reflected light.

During polishing of the substrate W, as a rinse liquid, pure water is supplied to the first hole 50A via the liquid supply line 53 and further supplied to the through hole 51 through the first hole 50A. The pure water fills space between the surface (the surface to be polished) of the substrate W and the optical sensor head 7. The pure water flows into the second hole 50B and is discharged through the drain line 54. The pure water flowing inside the first hole 50A and the through hole 51 prevents the slurry from entering the first hole 50A, and this ensures an optical path.

The liquid supply line 53 and the drain line 54 are connected to a rotary joint 19 and further extends inside the polishing table 3. One end of the liquid supply line 53 is connected to the first hole 50A. The other end of the liquid supply line 53 is connected to a pure water supply source that is not illustrated. The pure water is supplied to the first hole 50A through the liquid supply line 53 and further supplied to the through hole 51 through the first hole 50A.

The liquid supply line 53 and the drain line 54 are connected to the rotary joint 19 and further extends inside the polishing table 3. One end of the liquid supply line 53 is connected to the first hole 50A. The other end of the liquid supply line 53 is connected to a pure water supply source that is not illustrated. The pure water is supplied to the first hole 50A through the liquid supply line 53 and further supplied to the through hole 51 through the first hole 50A.

One end of the drain line 54 is connected to the second hole 50B. The pure water supplied to the through hole 51 flows through the second hole 50B and further is discharged outside the substrate polishing apparatus through the drain line 54. An open/close valve 68 is mounted to the liquid supply line 53. The open/close valve 68 is an electromagnetic valve or an electric valve. The open/close valve 68 is electrically connected to the control device 9. During polishing of the substrate W, the control device 9 periodically opens and closes the open/close valve 68 in synchronization with the rotation of the polishing table 3. Specifically, the control device 9 closes the open/close valve 68 when the substrate W is not present on the through hole 51, and the control device 9 opens the open/close valve 68 when the substrate W is present on the through hole 51.

The above-described embodiment is an example of a so-called water seal type in which the space between the surface (the surface to be polished) of the substrate W and the optical sensor head 7 is filled with pure water. As another embodiment, instead of securing the optical path of the optical sensor head 7 by using a water seal type, a configuration in which a polishing pad having a transparent window is attached to the polishing table may be employed. For example, a method using a transparent window is disclosed in Japanese Unexamined Patent Application Publication No. 2017-220683 (PTL 2).

The rotary encoders 11, 14 are electrically connected to the control device 9, and an output signal (that is, a detected value of the rotation angle of the polishing table 3) of the rotary encoder 11 and an output signal (that is, a position of the substrate holding head 1) of the rotary encoder 14 are transmitted to the control device 9. The control device 9 can determine a relative position of the optical sensor head 7 relative to the substrate holding head 1 from the output signal of the rotary encoder 11, that is, the rotation angle of the polishing table 3 and the output signal of the rotary encoder 14, that is, the position of the substrate holding head 1, and can control light detection timing of the optical detector 48 based on the relative position of the optical sensor head 7. As described later, the control device 9 can control an exposure time based on the rotation speed of the polishing table 3 obtained from the rotary encoder 11.

As illustrated in FIGS. 1 and 2, the substrate polishing apparatus includes a trigger sensor 25. As illustrated in FIG. 2, the trigger sensor 25 is mounted to the polishing table 3 and rotatable together with the polishing table 3. As illustrated in FIG. 2, in the substrate polishing apparatus, a dog 27 is disposed outside the polishing table 3. The trigger sensor 25 is configured to detect the dog 27 each time the polishing table 3 rotates once to generate a trigger signal. The trigger signal is transmitted to the control device 9. In one embodiment, the light detection timing of the optical detector 48 can be controlled based on the trigger signal generated from the trigger sensor 25.

During polishing of the substrate W, the control device 9 issues a command to the optical detector 48 to control light detection operation of the optical detector 48. Namely, when the optical sensor head 7 is present below the substrate W, the control device 9 transmits a light detection trigger signal to the optical detector 48. When receiving the light detection trigger signal, the optical detector 48 starts capturing the reflected light, and when transmission of the light detection trigger signal is halted, the optical detector 48 halts capturing of the reflected light.

In this specification, a time for each operation of the optical detector 48 to capture the reflected light is referred to as an exposure time. During the exposure time, the optical detector 48 continues to capture the reflected light (continues to detect the reflected light). The optical detector 48 has an electronic shutter function. Namely, when the optical detector 48 receives the light detection trigger signal, an electronic shutter opens, and when the transmission of the light detection trigger signal is halted, the electronic shutter closes. The exposure time is a time from a time point when the electronic shutter opens to a time point when the electronic shutter closes. While, in this embodiment, the shutter has the electronic shutter function included in the optical detector 48, in another embodiment, the shutter may be a mechanical shutter disposed in front of the optical detector 48 or the spectroscope 47. As one embodiment, both of a mechanical shutter and the electronic shutter function may be used. Even when a mechanical shutter is used, the operation can be configured to be controlled by the control device 9. Even when a mechanical shutter is used, the exposure time is a period for which the optical detector 48 receives the reflected light and captures the reflected light. The exposure time can also be referred to as an opening time during which a shutter is open.

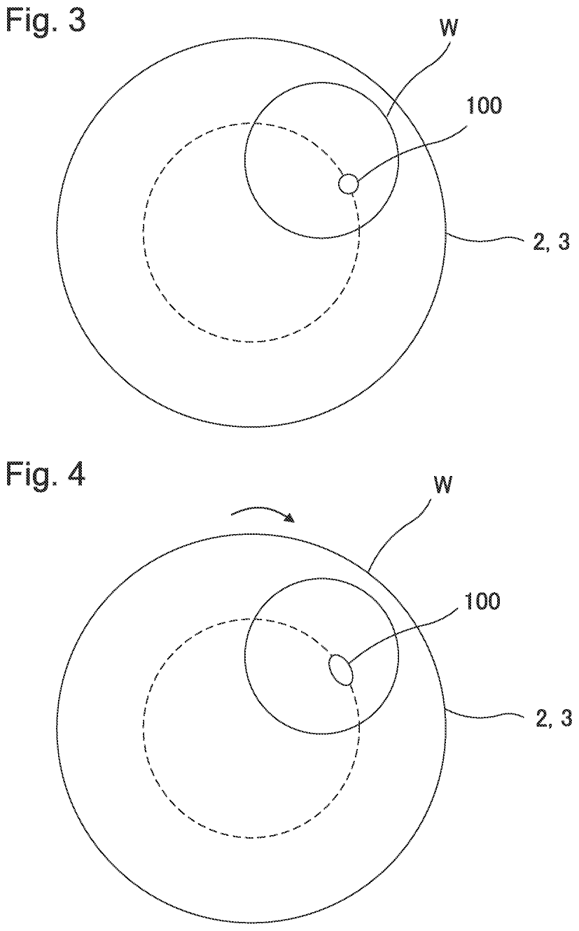

The following describes control of the exposure time according to one embodiment. FIG. 3 is a diagram schematically illustrating a positional relationship between the polishing table 3 and the substrate W held by the substrate holding head 1 in a state where the polishing table 3 and the substrate holding head 1 are halted, and illustrates a measurement region 100 (an irradiated region) on the substrate W in a certain exposure time. As described above, the optical sensor head 7 is disposed in the polishing table 3, and the substrate W is irradiated with the light from the light projection port 31a of the light projection optical fiber cable 31. As illustrated in FIG. 3, in the state where the polishing table 3 and the substrate holding head 1 are halted, the measurement region 100 on the substrate W that is irradiated from the light projection port 31a is minimum and constant.

FIG. 4 is a diagram schematically illustrating a positional relationship between the polishing table 3 and the substrate W held by the substrate holding head 1 in a state where the polishing table 3 is relatively rotating at a low velocity and the substrate holding head 1 is halted, and illustrates the measurement region 100 (the irradiated region) on the substrate W in a certain exposure time. In the condition illustrated in FIG. 4, since the polishing table 3 is rotating, the optical sensor head 7 is also rotating, and the irradiated light travels on the substrate W during a certain exposure time, the measurement region 100 becomes larger than that in the case in FIG. 3.

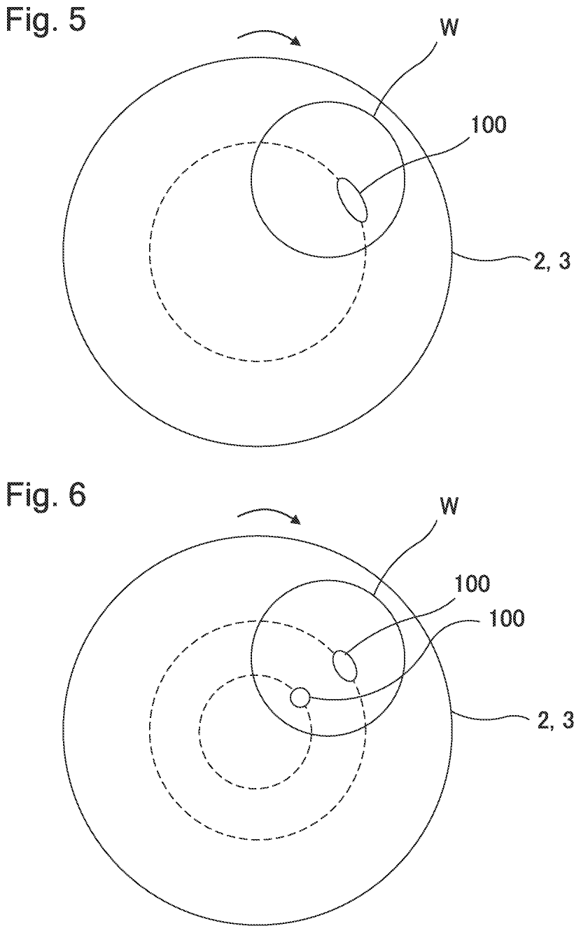

FIG. 5 is a diagram schematically illustrating a positional relationship between the polishing table 3 and the substrate W held by the substrate holding head 1 in a state where the polishing table 3 is relatively rotating at a high velocity and the substrate holding head 1 is halted, and illustrates the measurement region 100 (the irradiated region) on the substrate W in a certain exposure time. In the condition illustrated in FIG. 5, since the polishing table 3 is rotating at a high velocity, the measurement region 100 becomes still larger than that in the case in FIG. 4.

As described above, when the exposure time is constant, the area of the measurement region 100 varies depending on the rotation speed of the polishing table 3. Thus, the measurement accuracy of the surface condition of the substrate W in the optical surface monitoring system 40 is influenced by the rotation speed of the polishing table 3.

Thus, in one embodiment, the control device 9 changes the exposure time in accordance with the rotation speed of the polishing table 3 so that the measurement region 100 has a substantially constant area irrespective of the rotation speed of the polishing table 3. The area of the measurement region need not be completely constant, and it is only necessary that the exposure time is changed such that a variation in the area of the measurement region when the exposure time is constant is reduced.

In one embodiment, first, a reference exposure time (ExpTstd) at a reference rotation speed (TTstd) of the polishing table 3 is defined. The travel distance of the optical sensor head 7 within the exposure time is proportionate to the rotation speed of the polishing table 3. Thus, the area of the measurement region 100 is proportionate to the travel distance of the optical sensor head 7, namely, the rotation speed of the polishing table 3 within the exposure time. When the polishing table 3 is rotating at an optional rotation speed (TT), the exposure time (ExpT(TT)) in which the travel distance of the optical sensor head 7 becomes identical to when the polishing table 3 is rotating at the reference rotation speed (TTstd) is expressed as follows.

ExpT(TT)=ExpTstd×(TTstd/TT)

In other words, it can be said that the reference exposure time is corrected using the rotation speed of the polishing table 3.

As the rotation speed (TT) of the polishing table 3 when the substrate W is being polished, one that is determined by the user of the substrate polishing apparatus can be used. As illustrated in FIG. 2, the substrate polishing apparatus includes the operation PC 29. The operation PC constitutes the user interface of the substrate polishing apparatus, and allows the user to specify the polishing conditions such as the rotation speed (TT) of the polishing table 3, and the like. In one embodiment, since the substrate polishing apparatus includes the rotary encoder 11 and the rotation speed of the polishing table 3 during polishing can be measured, it is possible to utilize the measured rotation speed of the polishing table 3. In one embodiment, the rotation speed of the polishing table 3 may be measured from timing at which the trigger sensor 25 issues the trigger signal. In this specification, the polishing conditions include not only conditions specified by the user but also conditions actually achieved in the substrate polishing apparatus. For example, the polishing conditions include not only the rotation speed (TT) of the polishing table 3 specified by the user but also the rotation speed of the polishing table 3 measured in the substrate polishing apparatus.

FIG. 6 is a diagram schematically illustrating a positional relationship between the polishing table 3 and the substrate W held by the substrate holding head 1 in a state where the plurality of optical sensor heads 7 are disposed in a radial direction of the polishing table 3, the polishing table 3 is rotating, and the substrate holding head 1 is halted, and illustrates the measurement region 100 (the irradiated region) on the substrate W in a certain exposure time.

As illustrated in FIG. 6, even when the polishing table 3 is rotating at a constant rotation speed, the travel distance of the optical sensor head 7 within the exposure time varies depending on a radial direction position of the optical sensor head 7. Thus, in one embodiment, the exposure time is changed in accordance with the radial direction position of the optical sensor head 7.

When the polishing table 3 is rotating at a constant rotation speed, the travel distance of the optical sensor head 7 is proportionate to the radial direction position. Thus, the exposure time is determined such that the travel distance becomes identical no matter at which radial direction position the optical sensor head 7 is present. The exposure time (ExpT(r)) used for measurement by the optical sensor head 7 located at an optional radial direction position (r) with respect to the reference exposure time (ExpTstd) relative to a reference position (r0) of the optical sensor head 7 is expressed as follows.

ExpT(r)=ExpTstd×(r0/r)

In other words, it can be said that the reference exposure time is corrected using the radial direction position of the optical sensor head 7.

While FIG. 6 is an example of a case where the substrate polishing apparatus includes the plurality of optical sensor heads 7, even when one optical sensor head 7 can travel in the radial direction, the exposure time can be similarly corrected.

In one embodiment, of the above-described correction of the exposure time based on the rotation speed of the polishing table 3 and the above-described correction of the exposure time based on the radial direction position of the polishing table 3, only one may be employed, or both of them may be employed.

While the above-described correction of the exposure time is performed in a case where the substrate holding head 1 is not rotating during polishing, or in a case where the rotation of the substrate holding head 1 is not taken into consideration even when the substrate holding head 1 is rotating, in one embodiment the exposure time may be corrected in consideration of the rotation of the substrate holding head 1.

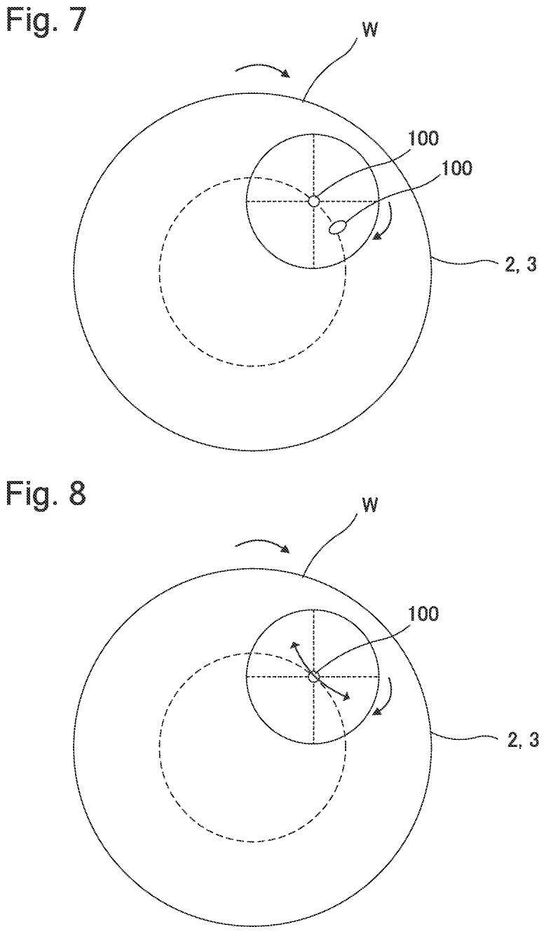

FIG. 7 is a diagram schematically illustrating a positional relationship between the polishing table 3 and the substrate W held by the substrate holding head 1 in a state where the polishing table 3 and the substrate holding head 1 are rotating, and illustrates the measurement region 100 (the irradiated region) on the substrate W in a certain exposure time. In the condition illustrated in FIG. 7, since not only the polishing table 3 but also the substrate holding head 1 is rotating, the size of the measurement region 100 varies depending on the radial direction position of the optical sensor head 7 on the substrate W. Thus, in one embodiment, the exposure time is corrected such that the measurement region 100 has a constant size even in the state where the polishing table 3 and the substrate holding head 1 are rotating.

The position of the optical sensor head 7 disposed in the rotating polishing table 3 can be determined by design information of the substrate polishing apparatus, the rotation speed of the polishing table 3, and a time after the trigger sensor 25 has reacted. The center of the substrate W is equal to a rotational center of the substrate holding head 1 and is a value determined by the design information. The radial direction position on the substrate W measured by the optical sensor head 7 can be determined from the radial direction position of the optical sensor head 7 on the polishing table 3 and the distance from the center of the substrate holding head 1. A travel distance L on the substrate W in a certain exposure time of an optional optical sensor head 7 is determined by composition of a travel distance component Ltt (x1,y1) based on the rotation of the polishing table 3 and a travel distance component Ltr (x2,y2) based on the rotation of the substrate holding head 1 as follows.

$$L = \sqrt{{\{ Ltt ( x 1 ) + Ltr ( x 2 ) \}}^{2} + {\{ Ltt ( y 1 ) + Ltr ( y 2 ) \}}^{2}}$$

Assuming that the travel distance of the measurement region 100 at the reference rotation speed (TTstd) of the polishing table 3 is L0, an exposure time ExpT(r) at an optional radial position r on the substrate W can be determined as follows.

ExpT(r)=ExpTstd×(L/L0)

As described above, in one embodiment, during polishing of the substrate, the substrate holding head 1 may be swung on the polishing pad 2 by turning the arm 13. FIG. 8 is a diagram schematically illustrating a positional relationship between the polishing table 3 and the substrate W held by the substrate holding head 1 in a state where the polishing table 3 is rotating and the substrate holding head 1 is rotating while swinging, and illustrates the measurement region 100 (the irradiated region) on the substrate W in a certain exposure time. When the substrate holding head 1 is swung on the polishing pad 2 during polishing of the substrate, the center of the substrate W travels during the exposure time. Thus, in consideration of the swing of the substrate holding head 1 by the arm 13, the exposure time may be corrected. The swing speed of the substrate holding head 1 by the arm 13 can be controlled by the control device 9.

When the substrate holding head 1 is swung, the measurement region 100 varies depending on a relationship between a rotation direction of the polishing table 3 and a swing direction of the substrate holding head 1. When the swing direction of the substrate holding head 1 is an identical direction to the rotation direction of the polishing table 3, the relative travel distance of the optical sensor head 7 during the exposure time is decreased, and the measurement region 100 becomes smaller, and thus, the exposure time is corrected to be longer. Conversely, when the swing direction of the substrate holding head 1 is an opposite direction to the rotation direction of the polishing table 3, the relative travel distance of the optical sensor head 7 during the exposure time is increased, and the measurement region 100 becomes larger, and thus, the exposure time is corrected to be shorter.

As described above, according to the present disclosure, when the surface condition of the substrate is monitored using the optical surface monitoring system, in consideration of the travel of the irradiated region by the light during the exposure time, the exposure time can be corrected such that the measurement region 100 is constant. Therefore, the influence on the measurement accuracy due to a change in the area of the measurement region 100 can be removed or reduced. In particular, as the light source of the optical surface monitoring system, using the CW light source in which the exposure time easily becomes longer is more effective.

In the description of the above-described embodiment, while it is described that the exposure time is corrected such that the measurement region 100 has a constant area, the measurement region 100 need not have a completely constant area by the correction. Compared to a case where no correction is made at all, this is because when the correction is made such that the change in the area of the measurement region 100 under various polishing conditions becomes small, the influence of the change in the area of the measurement region 100 on the measurement accuracy can be reduced.

While several embodiments of the present invention have been described above, the above-described embodiments of the present invention are intended to facilitate understanding of the present invention and do not limit the present invention. The present invention may be modified and improved without departing from its spirit, and it goes without saying that the present invention includes equivalents of the present invention. To the extent that at least part of the above-described problems can be solved, or to the extent that at least part of the effect is achieved, any combination or omission of each component described in the claims and specification is possible.

From the above-described embodiments, at least the following technical ideas are obtained.

### [Configuration 1]

According to a configuration 1, a substrate polishing apparatus is provided. The substrate polishing apparatus includes a polishing table, a motor, a substrate holding head, a light source, an optical head, an optical detector, a shutter, and a control device. The motor is for rotating the polishing table. The substrate holding head is configured to hold a substrate. The optical head is disposed inside the polishing table. The optical head includes a light projection port and a light reception port. The light projection port is disposed to project light from the light source toward the substrate held by the substrate holding head. The light reception port is disposed to receive light reflected from the substrate held by the substrate holding head. The optical detector is for detecting the light received at the light reception port. The shutter is for controlling an exposure time during which the light is captured in the optical detector. The control device is for controlling operation of the shutter so as to change the exposure time based on a polishing condition of the substrate.

### [Configuration 2]

According to a configuration 2, in the substrate polishing apparatus according to the configuration 1, the control device determines the exposure time such that an area in which the substrate is irradiated with the light projected onto the substrate from the light projection port is substantially constant.

### [Configuration 3]

According to a configuration 3, in the substrate polishing apparatus according to the configuration 1 or the configuration 2, the exposure time is determined based on a rotation speed of the polishing table.

### [Configuration 4]

According to a configuration 4, in the substrate polishing apparatus according to any one configuration of the configuration 1 to the configuration 3, the exposure time is determined based on a distance from a rotational center of the polishing table to the optical head.

### [Configuration 5]

According to a configuration 5, the substrate polishing apparatus according to any one configuration of the configuration 1 to the configuration 4 further includes a second motor for rotating the substrate holding head. The exposure time is determined based on a rotation speed of the substrate holding head.

### [Configuration 6]

According to a configuration 6, the substrate polishing apparatus according to any one configuration of the configuration 1 to the configuration 5 further includes an arm for moving the substrate holding head in a direction parallel to a planar surface of the polishing table. The exposure time is determined based on a parallel travel velocity of the substrate holding head by the arm.

### [Configuration 7]

According to a configuration 7, the substrate polishing apparatus according to the configuration 1 further includes a second and a parallel travel mechanism. The second motor is for rotating the substrate holding head. The parallel travel mechanism is for moving the substrate holding head in a direction parallel to a planar surface of the polishing table. The exposure time is determined based on: (1) a rotation speed of the polishing table; (2) a distance from a rotational center of the polishing table to the optical head; (3) a rotation speed of the substrate holding head; and (4) a parallel travel velocity of the substrate holding head by the arm.

### [Configuration 8]

According to a configuration 8, in the substrate polishing apparatus according to any one configuration of the configuration 1 to the configuration 7, the light source is a continuous light-emitting light source.

### REFERENCE SIGNS LIST

1 . . . substrate holding head
2 . . . polishing pad
3 . . . polishing table
5 . . . slurry supply nozzle
7 . . . optical sensor head
9 . . . control device
11 . . . rotary encoder
13 . . . arm
14 . . . rotary encoder
15 . . . support pillar
25 . . . trigger sensor
40 . . . optical surface monitoring system
44 . . . CW light source
47 . . . spectroscope
48 . . . optical detector
100 . . . measurement region
31a . . . light projection port
32a . . . light reception port
W . . . substrate

What is claimed is:

1. A substrate polishing apparatus comprising:
a polishing table;
a motor for rotating the polishing table;
a substrate holding head configured to hold a substrate;
a light source;
an optical head disposed inside the polishing table, the optical head including:
a light projection port disposed to project light from the light source toward the substrate held by the substrate holding head; and
a light reception port disposed to receive light reflected from the substrate held by the substrate holding head;
an optical detector for detecting the light received at the light reception port;
a shutter for controlling an exposure time during which the light is captured in the optical detector; and
a control device for controlling operation of the shutter so as to change the exposure time based on a polishing condition of the substrate.

2. The substrate polishing apparatus according to claim 1, wherein
the control device determines the exposure time such that an area in which the substrate is irradiated with the light projected onto the substrate from the light projection port is substantially constant.

3. The substrate polishing apparatus according to claim 1, wherein
the exposure time is determined based on a rotation speed of the polishing table.

4. The substrate polishing apparatus according to claim 1, wherein
the exposure time is determined based on a distance from a rotational center of the polishing table to the optical head.

5. The substrate polishing apparatus according to claim 1, further comprising
a second motor for rotating the substrate holding head, wherein
the exposure time is determined based on a rotation speed of the substrate holding head.

6. The substrate polishing apparatus according to claim 1, further comprising
an arm for moving the substrate holding head in a direction parallel to a planar surface of the polishing table, wherein
the exposure time is determined based on a parallel travel velocity of the substrate holding head by the arm.

7. The substrate polishing apparatus according to claim 1, further comprising:
a second motor for rotating the substrate holding head; and
a parallel travel mechanism for moving the substrate holding head in a direction parallel to a planar surface of the polishing table, wherein
the exposure time is determined based on:
(1) a rotation speed of the polishing table;
(2) a distance from a rotational center of the polishing table to the optical head;
(3) a rotation speed of the substrate holding head; and
(4) a parallel travel velocity of the substrate holding head by the arm.

8. The substrate polishing apparatus according to claim 1, wherein
the light source is a continuous light-emitting light source.
